(19) United States
(12) Patent Application Publication
(10) Pub. No.: US 2007/0249151 A1
(43) Pub. Date: Oct. 25, 2007

(54) METHOD OF MANUFACTURING SEMICONDUCTOR DEVICE AND SEMICONDUCTOR DEVICE

(75) Inventor: Tomohiro Kadoya, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: ELPIDA MEMORY, INC., Tokyo (JP)

(21) Appl. No.: 11/691,252

(22) Filed: Mar. 26, 2007

(30) Foreign Application Priority Data
Apr. 24, 2006 (JP) 2006-119723

(51) Int. Cl. H01L 21/44; H01L 21/4763

(52) U.S. Cl. 438/597; 438/622

(57) ABSTRACT

Gate electrodes each covered by protective insulating films are formed, a first interlayer insulating film is formed on the entire surface including regions between the protective insulating films and on the protective insulating films, the first interlayer insulating film is polished and removed until top surfaces of the protective insulating films are exposed, a second interlayer insulating film is subsequently formed on the entire surface, and the first and second interlayer insulating films formed between the gate electrodes are etched in a self-aligned manner, whereby contact holes are formed. Thereafter, a conductive film is formed on the entire surface so that the contact holes are buried, and the conductive film is polished and removed until the top surface of the second interlayer insulating film is exposed, whereby contact plugs buried in the contact holes are formed.

### TECHNICAL FIELD

The present invention relates to a method of manufacturing a semiconductor device and a semiconductor device. More particularly, the invention relates to a method of manufacturing a semiconductor device and a semiconductor device in which a SAC (Self Aligned Contact) process is used.

### BACKGROUND OF THE INVENTION

In recent years, along with the miniaturization of DRAM (Dynamic Random Access Memory) cells, the distance between gate electrodes of adjacent memory cell transistors has become remarkably narrow. Therefore, a SAC process is often used as a process for forming contact plugs (hereinafter, also “cell contacts”) connected to source/drain diffusion layers of the memory cell transistors in a self-aligned manner.

A conventional method of forming cell contacts according to a SAC process is explained below.

As shown in FIG. 25A, a gate insulating films 13 is formed on a semiconductor substrate 11 in which STIs (Shallow Trench Isolations) 12 as element isolating regions are formed. On top thereof, a conductive film that serves as gate electrodes and a silicon nitride film that serves as cap insulating films are stacked. Subsequently, the conductive film and the silicon nitride film are patterned to form a plurality of gate electrodes 14 and cap insulating films 16a. Thereafter, LDD (Lightly Doped Drain) regions are formed, and sidewall insulating films (silicon nitride films) 16b that cover side surfaces of the gate electrodes 14 and the cap insulating films 16a are formed. Thereby, a plurality of protective insulating films 16 that cover the side surface and a top surface of each of the gate electrodes 14 are formed. Subsequently, by using the protective insulating films 16 as a mask, impurities are implanted into the semiconductor substrate 11 to form source/drain diffusion layers 15. A structure shown in FIG. 25A is obtained in this way.

Subsequently, as shown in FIG. 25B, an interlayer insulating film (for example, a BPSG film) 17 is formed on the entire surface so that spaces between the plurality of protective insulating films 16 are buried.

Thereafter, as shown in FIG. 25C, contact plugs (cell contacts) 18 are formed according to the SAC process. That is, a mask layer (not shown) is formed on the interlayer insulating film 17, and the interlayer insulating film 17 is etched using the mask layer to thereby form a contact hole on each source/drain diffusion layer in a self-aligned manner. Subsequently, a conductive film (for example, a DOPOS (doped polysilicon) film) is formed so that the contact holes are buried thereby to form the cell contacts 18 connected to the source/drain diffusion layers 15.

The formation of the cell contacts 18 in this way permits widening of top diameters of the cell contacts 18. This is to ensure obtaining a contact area between the cell contacts, and capacitor contact plugs (not shown, hereinafter also “capacitor contacts”) formed on the cell contacts 18, or bit line contact plugs (not shown, hereinafter also “bit contacts”).

To prevent a SAC fracture in the SAC process, the interlayer insulating film 17 in which the cell contacts 18 are formed needs to be formed sufficiently thick.

The SAC fracture means that the protective insulating film (silicon nitride film) 16 that cover the gate electrode 14 is etched, and thereby the gate electrode 14 is exposed, resulting in the gate electrode 14 and the cell contact 18 being short-circuited. That is, in the formation of the contact holes in the SAC process, etching with a high selective ratio to the silicon nitride films, which are the protective insulating films 16, is performed. Even so, as shown in FIG. 25C, upper ends of the protective insulating films 16 are etched to a certain degree. Accordingly, when the interlayer insulating film 17 is thin, a time period during which the protective insulating films 16 are exposed to the etching is long. Consequently, an amount by which the protective insulating films are etched becomes large, resulting in a portion of the gate electrodes 14 being exposed, whereby the gate electrodes 14 end up with being in a contact with the contact plugs 18.

Accordingly, in order to widen the top diameters of the cell contacts 18 and to prevent the SAC fracture in the SAC process, it is necessary that the interlayer insulating film 17 in which the cell contacts 18 are formed is formed sufficiently thick.

However, when the interlayer insulating film 17 is thick, the capacitance between the adjacent cell contacts 18 becomes large by as much as the thickness, whereby a bit line capacitance (Cb) increases.

Methods of manufacturing a semiconductor device using a SAC process are disclosed, for example, in Japanese Patent Application Laid-open Nos. 2005-129938 and 2005-057303. In Japanese Patent No. 3195785, a related art to the present invention is described.

### SUMMARY OF THE INVENTION

The present invention has been achieved to solve the above problems. It is therefore an object of the present invention is to provide a method of manufacturing a semiconductor device and a semiconductor device, which uses a SAC process and capable of inhibiting an increase of a bit line capacitance (Cb), preventing a SAC fracture, and sufficiently widening top diameters of cell contacts.

The manufacturing method of a semiconductor device according to the present invention includes steps of: forming a plurality of gate electrodes on a semiconductor substrate; forming a plurality of protective insulating films that cover a top surface and side surfaces of each of the plurality of gate electrodes; forming a plurality of source/drain diffusion layers in the semiconductor substrate by introducing impurities into the semiconductor substrate using the protective insulating films as a mask; forming a first interlayer insulating film on an entire surface including regions between the protective insulating films and on the protective insulating films; removing the first interlayer insulating film formed on the protective insulating films by polishing until top surfaces of the protective insulating films are exposed; forming a second interlayer insulating film on an entire surface including on the top surfaces of the exposed protective insulating films; forming a plurality of contact holes by etching the second interlayer insulating film and the first interlayer insulating film formed between the gate electrodes in a self-aligned manner; forming a conductive film on an entire surface so that the plurality of contact holes are filled; and forming a plurality of first contact plugs filled in the plurality of contact holes by removing the conductive film formed on the second interlayer insulating film by polishing until a top surface of the second interlayer insulating film is exposed.

The semiconductor device according to the present invention includes: a plurality of gate electrodes formed on a semiconductor substrate; a plurality of protective insulating films that cover a top surface and side surfaces of each of the plurality of gate electrodes; a plurality of source/drain diffusion layers formed in the semiconductor substrate; a first interlayer insulating film arranged between the plurality of protective insulating films; a second interlayer insulating film formed on an upper layer of the first interlayer insulating film; and plurality of first contact plugs arranged in a manner of penetrating the first and second interlayer insulating films, having bottom surfaces each being electrically connected to the source/drain diffusion layers, and configured such that top surfaces are approximately flush with a top surface of the second interlayer insulating film.

According to the present invention, since the second interlayer insulating film is formed on protective insulating films, upon forming contact holes in which first contact plugs are formed, that is, in etching in a SAC process, an amount by which the protective insulating films that cover shoulders of gate electrodes are etched is reduced, whereby a SAC fracture can be prevented.

In polishing and removing of a plug-use conductive film, the second interlayer insulating film functions as a stopper for polishing, so that top diameters of the first contact plugs (cell contacts) can be kept wide. Accordingly, a superimposed margin between the cell contacts and capacitor contacts formed thereon can be made large.

When a blanket insulating film that covers at least the protective insulating films is formed, upon removing the blanket insulating film on bottoms of the contact holes, the second interlayer insulating film functions as a hard mask, and thus, upper portions of the protective insulating films can be protected.

### BRIEF DESCRIPTION OF THE DRAWINGS

The above and other objects, features and advantages of this invention will become more apparent by reference to the following detailed description of the invention taken in conjunction with the accompanying drawings, wherein:

FIG. 1 is a cross-sectional view showing a step (formation of STI regions 102 to formation of a silicon nitride film 105) of a method of manufacturing a semiconductor device according to a first embodiment of the present invention;

FIG. 2 is a cross-sectional view showing a step (formation of a mask layer) of the method of manufacturing the semiconductor device according to the first embodiment of the present invention;

FIG. 3 is a cross-sectional view showing a step (formation of cap insulating films 105c and gate electrodes 104g) of the method of manufacturing the semiconductor device according to the first embodiment of the present invention;

FIG. 4 is a cross-sectional view showing a step (formation of LDD regions 107) of the method of manufacturing the semiconductor device according to the first embodiment of the present invention;

FIG. 5 is a cross-sectional view showing a step (formation of sidewall insulating films 105s and formation of source/drain diffusion layers 108) of the method of manufacturing the semiconductor device according to the first embodiment of the present invention;

FIG. 6 is a cross-sectional view showing a step (formation of a blanket insulating film 109) of the method of manufacturing the semiconductor device according to the first embodiment of the present invention;

FIG. 7 is a cross-sectional view showing a step (formation of a BPSG film 110) of the method of manufacturing the semiconductor device according to the first embodiment of the present invention;

FIG. 8 is a cross-sectional view showing a step (polishing and removing of the BPSG film 110) of the method of manufacturing the semiconductor device according to the first embodiment of the present invention;

FIG. 9 is a cross-sectional view showing a step (formation of an NSG film 111) of the method of manufacturing the semiconductor device according to the first embodiment of the present invention;

FIG. 10 is a cross-sectional view showing a step (formation of a mask layer 112) of the method of manufacturing the semiconductor device according to the first embodiment of the present invention;

FIG. 11 is a cross-sectional view showing a step (etching of the NSG film 111 and the BPSG film 110) of the method of manufacturing the semiconductor device according to the first embodiment of the present invention;

FIG. 12 is a cross-sectional view showing a step (etching back of the blanket insulating film 109) of the method of manufacturing the semiconductor device according to the first embodiment of the present invention;

FIG. 13 is a cross-sectional view showing a step (formation of a DOPOS film 114) of the method of manufacturing the semiconductor device according to the first embodiment of the present invention;

FIG. 14 is a cross-sectional view showing a step (polishing and removing of the DOPOS film 114) of the method of manufacturing the semiconductor device according to the first embodiment of the present invention;

FIG. 15 is a cross-sectional view showing a step (formation of an interlayer insulating film 115, a bit contact 116 and a bit line 117) of the method of manufacturing the semiconductor device according to the first embodiment of the present invention;

FIG. 16 is a cross-sectional view showing a step (formation of an interlayer insulating film 118 and capacitor contacts 119) of the method of manufacturing the semiconductor device according to the first embodiment of the present invention;

FIG. 17A is a layout diagram where capacitor contacts 119 are offset to cell contacts 114cp in the first embodiment;

FIG. 17B is a layout diagram where central regions of the cell contacts 114cp and the capacitor contacts 119 coincide;

FIG. 18 is a cross-sectional view showing a step (formation of an interlayer insulating film 120, formation of a capacitor (122, 123 and 124) and formation of an insulating film 125) of the method of manufacturing the semiconductor device according to the first embodiment of the present invention;

FIG. 19 is a cross-sectional view showing a step (formation of an epitaxial layer 200) of a method of manufacturing a semiconductor device according to a second embodiment of the present invention;

FIG. 20 is a cross-sectional view showing a step (formation of a mask layer 112) of the method of manufacturing the semiconductor device according to the second embodiment of the present invention;

FIG. 21 is a cross-sectional view showing a step (etching of an NSG film 111 and an BPSG film 110) of the method of manufacturing the semiconductor device according to the second embodiment of the present invention;

FIG. 22 is a cross-sectional view showing a step (etching back of a blanket insulating film 109) of the method of manufacturing the semiconductor device according to the second embodiment of the present invention;

FIG. 23 is a cross-sectional view showing a step (formation of a DOPOS film 114) of the method of manufacturing the semiconductor device according to the second embodiment of the present invention;

FIG. 24 is a cross-sectional view showing a step (polishing and removing of the DOPOS film 114) of the method of manufacturing the semiconductor device according to the second embodiment of the present invention; and

FIG. 25 is a process diagram schematically showing a manufacturing process of a semiconductor device according to a conventional method.

### DETAILED DESCRIPTION OF THE EMBODIMENTS

### First Embodiment

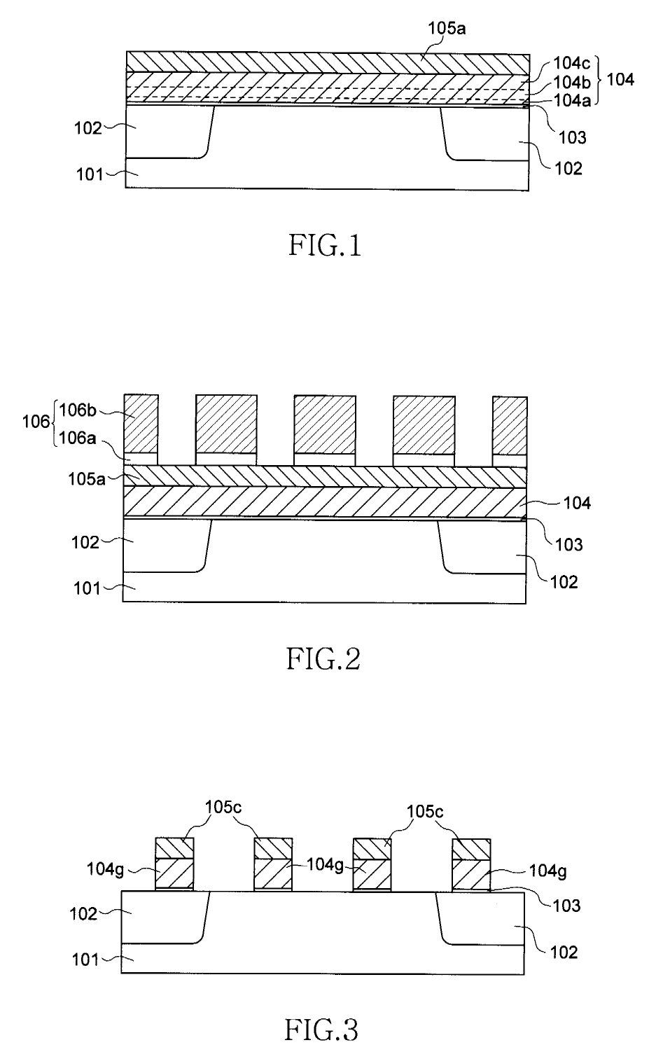

FIG. 1 to FIG. 16 and FIG. 18 are process diagrams schematically showing a manufacturing process of a semiconductor device according to a first embodiment of the present invention.

As shown in FIG. 1, STI regions 102 are formed in a semiconductor substrate 101. Subsequently, a gate insulating film 103 of about 70 nm in film thickness; a conductive film 104 as a gate electrode; and a silicon nitride film 105a, as a cap insulating film, of about 140 nm in film thickness are formed in this order. The conductive film 104 is configured by a DOPOS film 104a of about 70 nm in film thickness; a tungsten silicide (WSi) film 104b of about 5 nm in film thickness; and a multilayered film (W/WN) 104c comprised of a tungsten nitride of about 55 nm in film thickness and tungsten of about 10 nm in film thickness.

Subsequently, as shown in FIG. 2, mask layer 106 comprised of an antireflection film 106a and a photoresist film 106b is formed on the silicon nitride film 105a.

Thereafter, by using the mask layer 106, the silicon nitride film 105a, the conductive film 104, and the gate insulating film 103 are patterned to thereby obtain a structure as shown in FIG. 3. That is, a plurality of gate electrodes 104g and a plurality of cap insulating films 105c are formed on the gate insulating films 103.

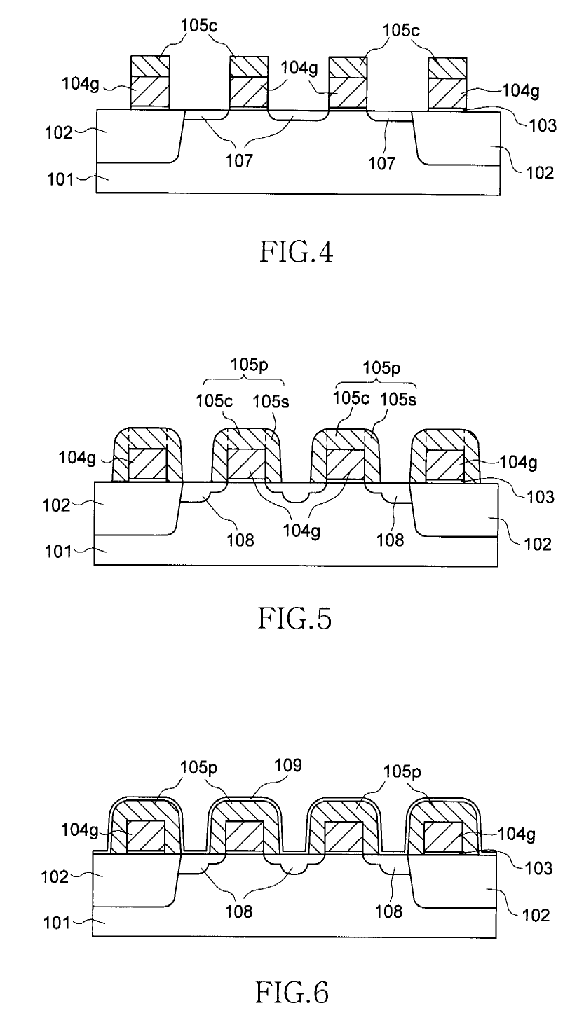

Subsequently, as shown in FIG. 4, by using the cap insulating films 105c and the gate electrodes 104g as a mask, impurities of which conductive type is opposite to that of the semiconductor substrate 101 are introduced (ion implantation) into the semiconductor substrate 101 to form LDD regions 107.

Thereafter, after forming a silicon nitride film on the entire surface, anisotropic etching (etch back) is performed to form sidewall insulating films 105s that cover side surfaces of the gate electrodes 104g and have a film thickness of about 22 nm, as shown in FIG. 5. Thereby, protective insulating films 105p, comprised of the cap insulating films 105c and the sidewall insulating films 105s, that cover the gate electrodes 104g are formed.

Subsequently, by using the protective insulating films 105p as a mask, impurities of which conductive type is opposite to that of the semiconductor substrate 101 is introduced (ion implantation) into the semiconductor substrate 101 to form source/drain diffusion layers 108.

Thereafter, as shown in FIG. 6, a blanket insulating film 109, comprised of a silicon nitride film, of about 13 nm in film thickness is formed on the entire surface.

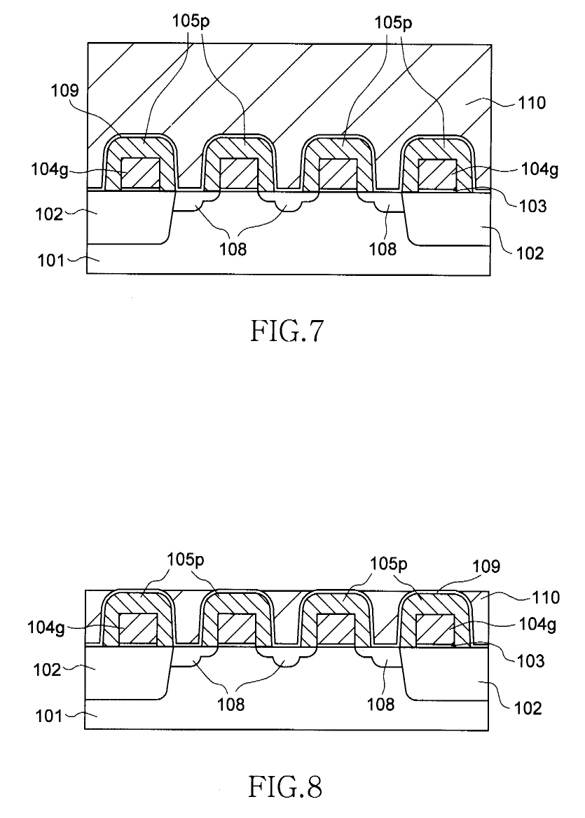

Subsequently, as shown in FIG. 7, a BPSG (Boro-Phospho Silicate Glass) film 110 of about 590 nm in film thickness is formed as an interlayer insulating film on the entire surface including between the adjacent protective insulating films 105p. The blanket insulating film 109 formed in FIG. 6 serves to protect the semiconductor substrate 101 against high temperatures (about 800° C.) when reflowing the BPSG film 110.

Thereafter, as shown in FIG. 8, the interlayer insulating film 110 is polished and removed by a CMP (Chemical Mechanical Polishing) method by using the blanket insulating film 109 as a stopper. Generally, in the CMP method, silica is used as slurry, but ceria slurry is preferably used herein. In the CMP where the ceria slurry is used, a silicon nitride film is hardly trimmed, so that the blanket insulating film 109 functions as an approximately complete stopper.

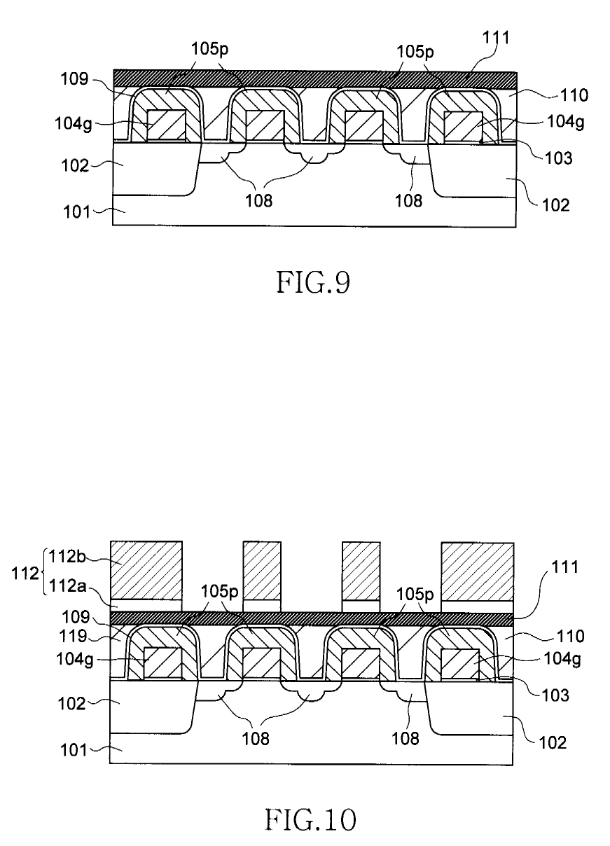

Thereafter, as shown in FIG. 9, an NSG (Non Silicate Glass) film 111 of about 200 nm in film thickness is formed as an interlayer insulating film on the entire surface.

Subsequently, as shown in FIG. 10, a mask layer 112 comprised of an antireflection film 112a and a photoresist film 112b is formed on the NSG film 111. The mask layer 112 has apertures positioned at upper portions of the source/drain diffusion layers 108. The width of the each aperture of the mask layer 112 is preferably set to be somewhat wider than distance between of shoulders of the adjacent protective insulating films 105p.

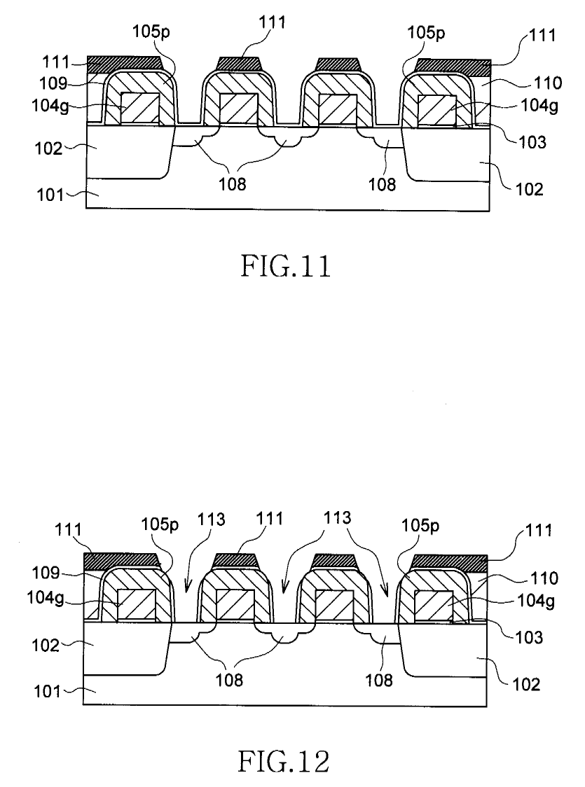

Thereafter, as shown in FIG. 11, by using the mask layer 112 shown in FIG. 10, the NSG film 111 and the BPSG film 110 below the apertures are sequentially etched and removed.

Subsequently, as shown in FIG. 12, by using the NSG film 111 as a mask, anisotropic etching (etch back) is performed to remove the blanket insulating film 109 on the source/drain diffusion layers 108. Thus, a plurality of contact holes 113 are formed in a self-aligned manner. In this etching, the function of the NSG film 111 as a hard mask provides protection of the shoulders of the protective insulating films 105p.

In this manner, the formation of the NSG film 111 on the protective insulating films 105p permits, (upon forming the contact holes 113, that is, upon etching in the SAC process,) suppressing of an amount by which the protective insulating films 105p that cover the shoulders of the gate electrodes 104 is etched, and preventing of a SAC fracture. Because of use of the blanket insulating film 109, it is necessary to remove the blanket insulating film 109 on bottoms of the contact holes 113. However, due to the function of the NSG film 111 as a hard mask upon removing, the upper portions (cap insulating films 105c) of the protective insulating films 105p are protected.

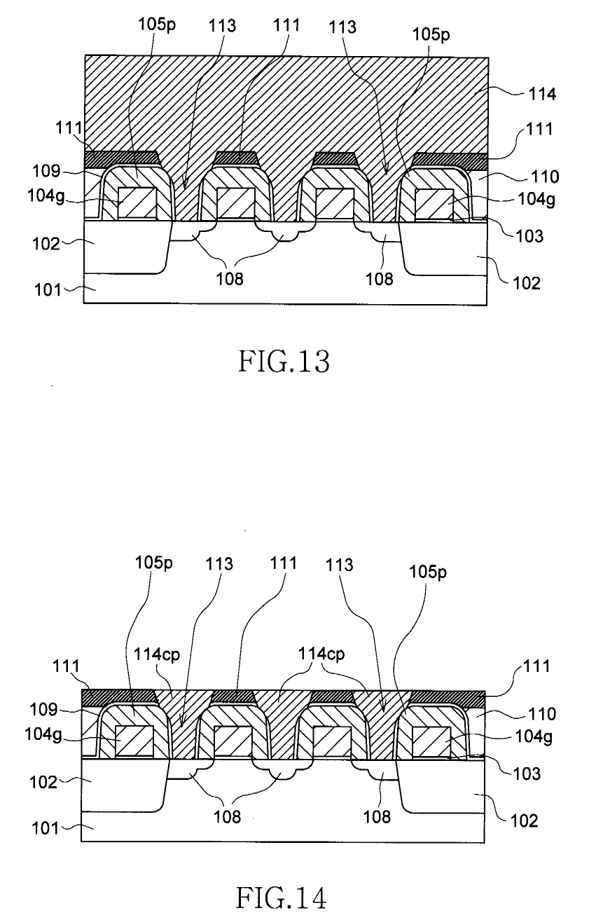

Thereafter, as shown in FIG. 13, a DOPOS film 114 of about 250 nm in film thickness as a conductive film is formed on the entire surface so that the contact holes 113 are buried.

Subsequently, as shown in FIG. 14, by using the NSG film 111 as a stopper, the DOPOS film 114 is polished and removed by a CMP method so that the DOPOS film 114 is retained in the contact holes 113 only. As a result, a contact plug (cell contact) 114cp is formed on each of the source/drain diffusion layers 108. Thus, the DOPOS film 114 is polished and removed so as to be rubbed and cut by the NSG film 111, thereby configuring such that top surfaces of the contact plugs 114cp are approximately flush with that of the NSG film, as shown in FIG. 14. Due to this configuration, top diameters of the contact plugs 114cp can be prevented from being narrow. In particular, in this embodiment, as shown in FIG. 10, since the widths of the apertures of the mask layer 112 are made wide, widths of apertures of the NSG film 111 can be made wide, whereby the top diameters of the contact plugs 114cp can be adequately made wide.

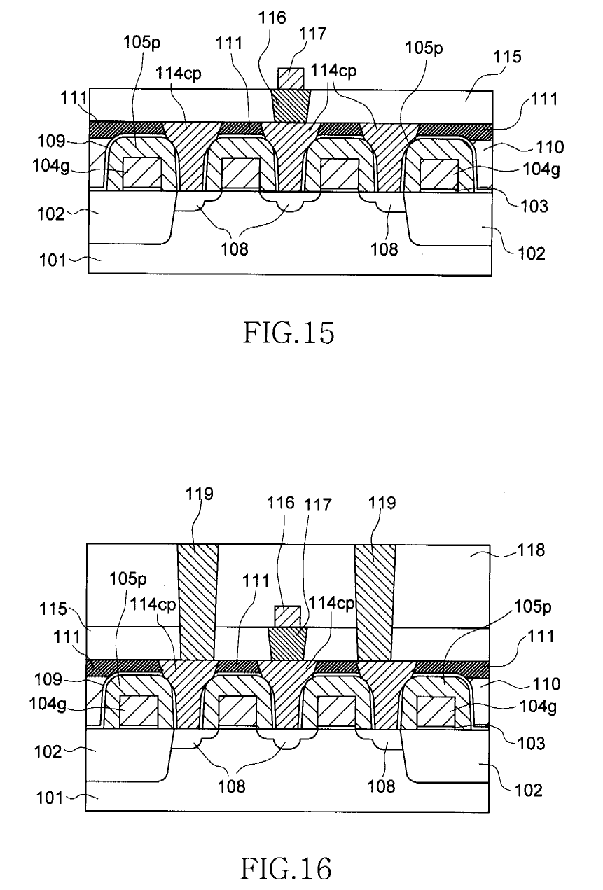

Subsequently, as shown in FIG. 15, an interlayer insulating film 115 of about 180 nm in film thickness is formed. Thereafter, a contact plug (bit contact) 116 that is connected to a center cell contact 114cp, out of the illustrated cell contacts 114cp, and a bit line 117 that is connected to the bit contact 116 is formed on the interlayer insulating film 115.

Subsequently, as shown in FIG. 16, an interlayer insulating film 118 of about 330 nm in film thickness is formed on the interlayer insulating film 115, and contact plugs (capacitor contacts) 119 that penetrate the interlayer insulating films 118 and 115 are formed. These capacitor contacts 119 are connected to the cell contacts 114cp on both sides, shown in FIG. 16, respectively. At this time, as explained above, the top diameters of the cell contacts 114cp are made wide, so that it is possible to increase a superimposed margin between each of the cell contacts 114cp and each of the capacitor contacts 119. Accordingly, as shown in FIG. 16, it is possible to offset the capacitor contacts 119 to the cell contacts 114cp.

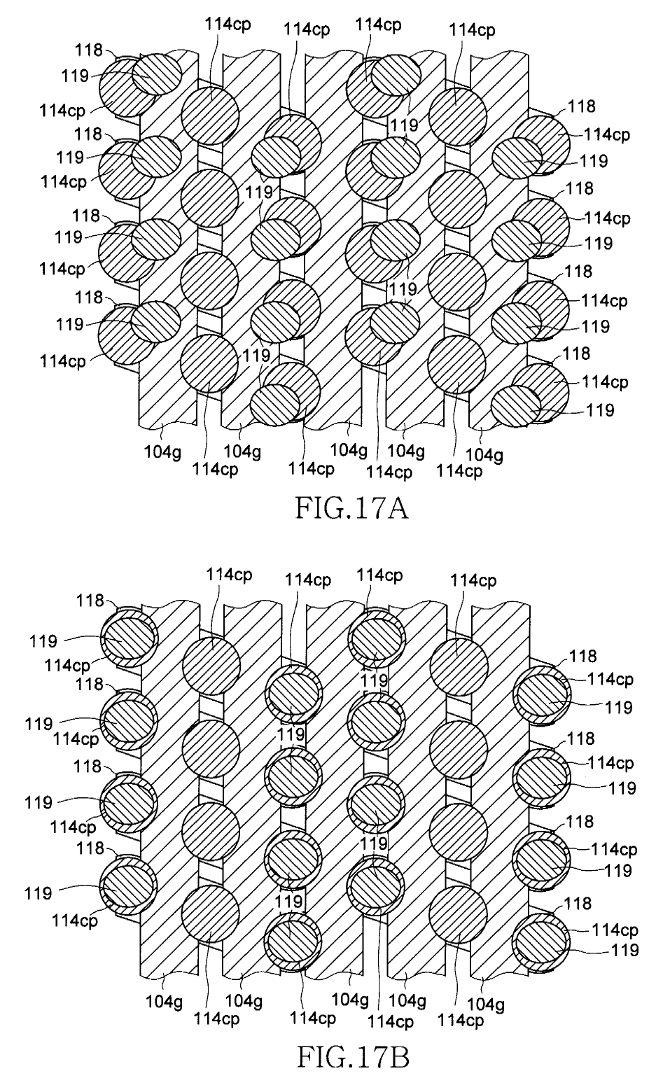

FIG. 17A shows a layout where the capacitor contacts 119 are offset to the cell contacts 114cp, and FIG. 17B shows a layout where each center of the capacitor contacts 119 and each center the cell contacts 114cp coincide. When each center of the capacitor contacts 119 and each center of the cell contacts 114cp coincide, layouts of the capacitor contacts 119 are nonuniform as shown in FIG. 17B. On the contrary, as shown in FIG. 17A, when the capacitor contacts 119 are offset to the cell contacts 114cp, the layouts of the capacitor contacts 119 can be made substantially uniform. Accordingly, it becomes possible to enlarge an exposure margin.

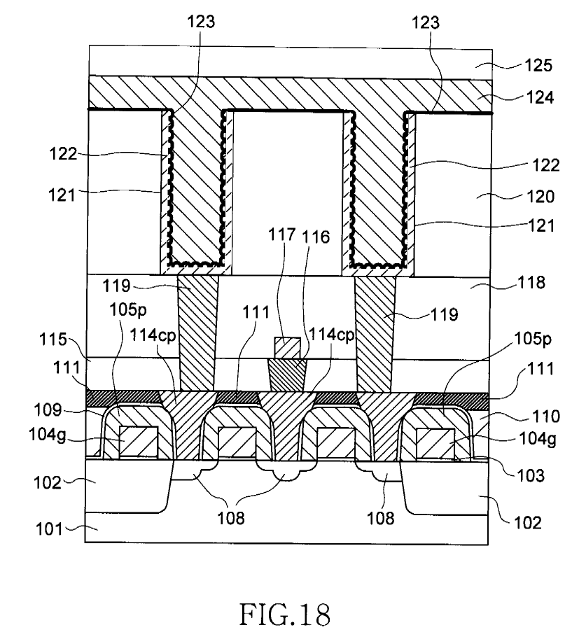

After forming the capacitor contacts 119, as shown in FIG. 18, an interlayer insulating film 120 of about 3000 nm in film thickness is formed on the interlayer insulating film 118, and openings 121 for forming capacitors are formed therein. Thereafter, lower electrodes 122, a capacitor insulating film 123, and an upper electrode 124 are sequentially formed in the openings 121, whereby a cylinder-type capacitors are formed. Subsequently, the entire surface is covered with an insulating film 125, thereby completing a memory cell transistor. It is preferable that in order to increase the capacitance, surfaces of the lower electrodes 122 be formed with HSGs (hemispherical grains), as shown in FIG. 18.

### Second Embodiment

A second embodiment of the present invention is explained below. In this embodiment, even when spaces between the gate electrodes become much narrower, it is still possible to surely connect the cell contacts and the source/drain diffusion layers electrically.

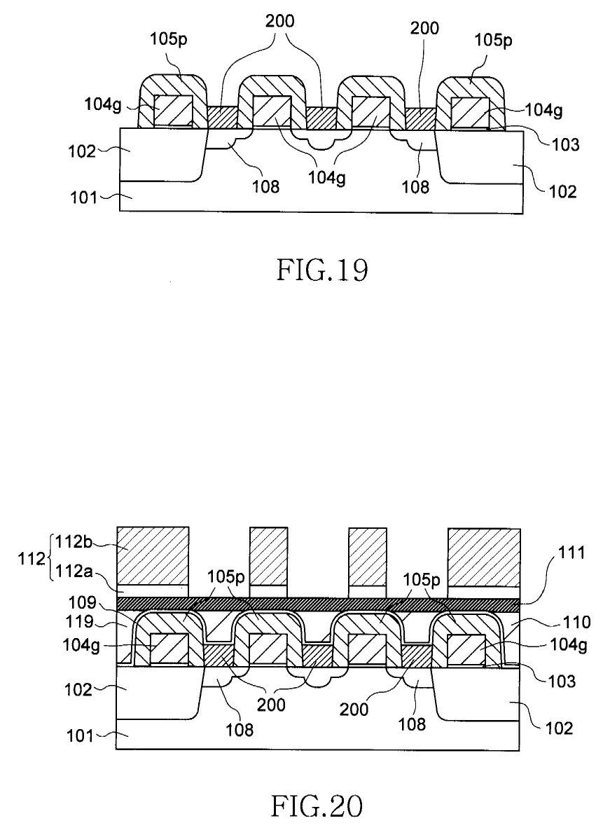

FIG. 19 to FIG. 24 are process diagrams schematically showing a portion of a manufacturing process of a semiconductor device according to the second embodiment. In the following explanations, steps that are the same as the above-mentioned first embodiment or similar are omitted for the simplification.

Firstly, the steps shown in FIG. 1 to FIG. 5 are performed similarly to the first embodiment. Thereafter, as shown in FIG. 19, epitaxial layers 200 are selectively formed on each of the source/drain diffusion layers 108 formed in the semiconductor substrate 101.

Subsequently, the steps similar to those shown in FIG. 6 to FIG. 10 are performed to obtain a structure shown in FIG. 20. As shown in FIG. 20, above the source/drain diffusion layers 108, the blanket insulating film 109 is formed on the epitaxial layers 200 formed in FIG. 19.

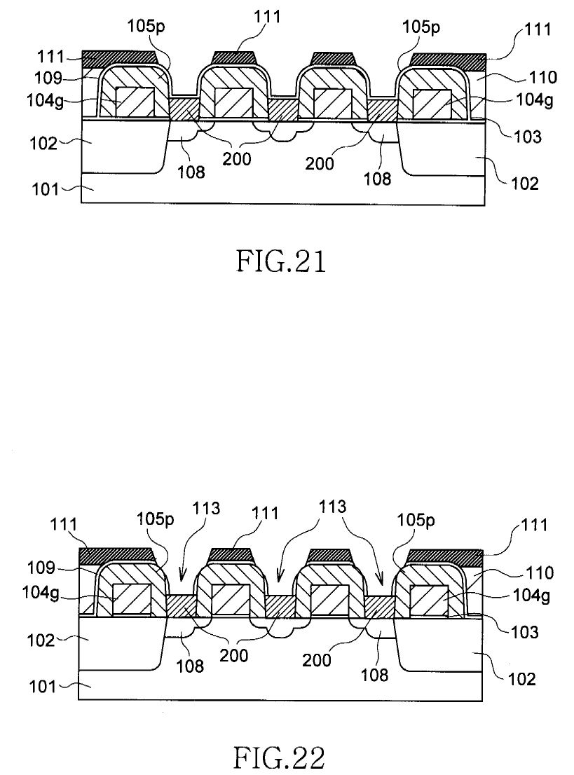

Thereafter, by using the mask layer 112, the NSG film 111 below the apertures of the mask layer 112 and the BPSG film 110 are sequentially etched and removed, as shown in FIG. 21.

Subsequently, as shown in FIG. 22, by using the NSG film 111 as a mask, anisotropic etching is performed to remove the blanket insulating film 109 on the epitaxial layers 200. Thereby, the contact holes 113 are opened, and on bottoms of the contact holes 113, top surfaces of the epitaxial layers 200 are exposed.

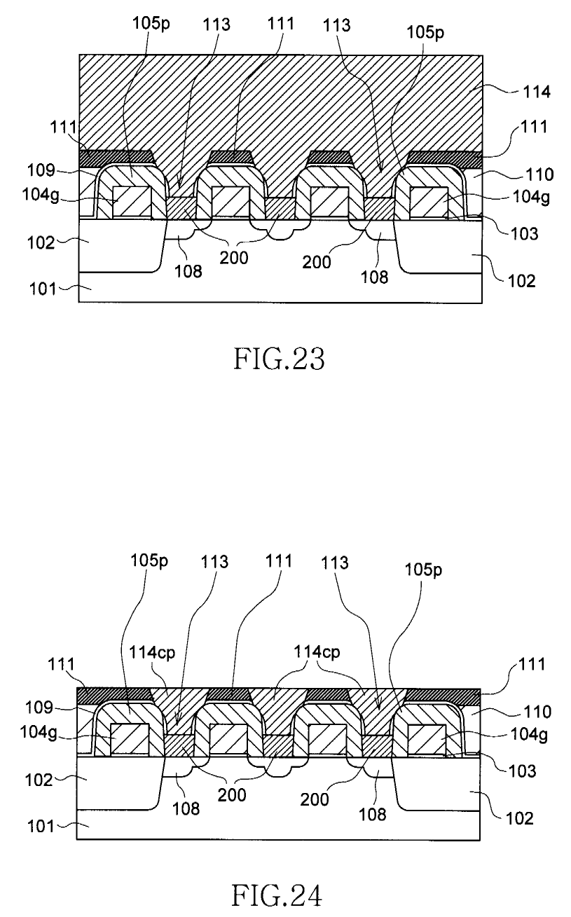

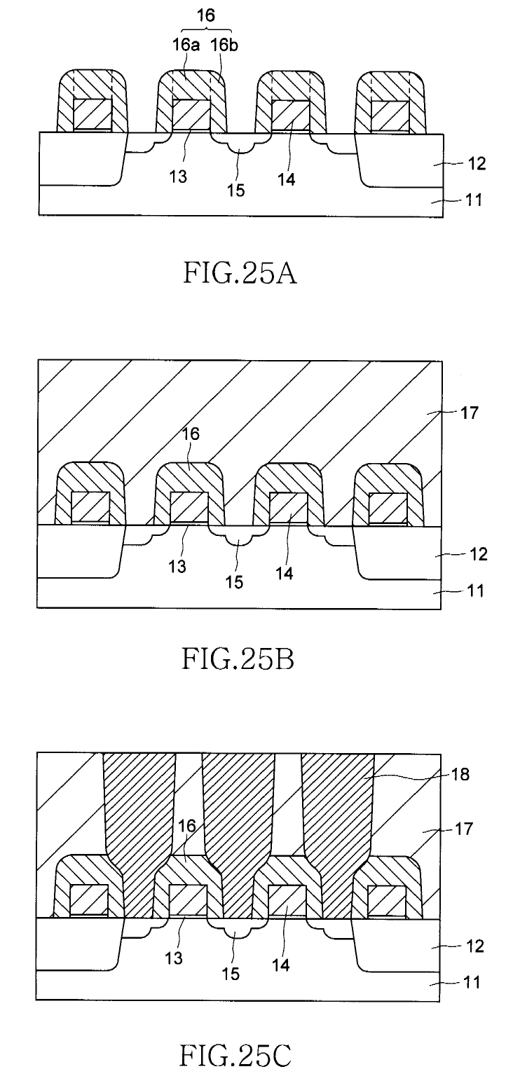

Thereafter, as shown in FIG. 23, the DOPOS film 114 is formed on the entire surface so that the contact holes 113 are buried. Upon burying the DOPOS film 114, according to the second embodiment, since the epitaxial layers 200 are formed on the source/drain diffusion layers 108, the DOPOS film 114 can be buried well.

Subsequently, as shown in FIG. 24, by using the NSG film 111 as a stopper, the DOPOS film 114 is polished and removed by the CMP method so that the DOPOS film 114 is retained in the contact holes 113 only, and the contact plugs 114cp connected to the epitaxial layers 200 are formed. Thereby, the contact plugs 114cp are electrically connected via the epitaxial layers 200 to the source/drain diffusion layers 108. Also in the second embodiment, similarly to the first embodiment, since the DOPOS film 114 is polished and removed so as to be rubbed and cut by the NSG film 111, it becomes possible to prevent top diameters of the contact plugs 114cp from becoming narrow.

Thereafter, the bit contact, the bit line, the capacitor contacts, the capacitor, and other components are formed similarly to the cases of the first embodiment shown in FIG. 15, FIG. 16 and FIG. 17.

Thus, according to the second embodiment, the presence of the epitaxial layers 200 enables the depth of the contact holes 113 that are opened to be shallow. Thus, even when intervals between the adjacent gate electrodes 104g are narrow and the aspect ratio is high, etching residues or the like are not generated, and favorable contact holes 113 can be formed.

While preferred embodiments of the present invention have been explained herein, this invention is not limited thereto. It is obvious that various modifications can be made without departing from the scope of the present invention and such modifications are embraced within the scope of the invention.

What is claimed is:

1. A manufacturing method of a semiconductor device, comprising steps of:
forming a plurality of gate electrodes on a semiconductor substrate;
forming a plurality of protective insulating films that cover a top surface and side surfaces of each of the plurality of gate electrodes;
forming a plurality of source/drain diffusion layers in the semiconductor substrate by introducing impurities into the semiconductor substrate using the protective insulating films as a mask;
forming a first interlayer insulating film on an entire surface including regions between the protective insulating films and on the protective insulating films;
removing the first interlayer insulating film formed on the protective insulating films by polishing until top surfaces of the protective insulating films are exposed;
forming a second interlayer insulating film on an entire surface including on the top surfaces of the exposed protective insulating films;
forming a plurality of contact holes by etching the second interlayer insulating film and the first interlayer insulating film formed between the gate electrodes in a self-aligned manner;
forming a conductive film on an entire surface so that the plurality of contact holes are filled; and
forming a plurality of first contact plugs filled in the plurality of contact holes by removing the conductive film formed on the second interlayer insulating film by polishing until a top surface of the second interlayer insulating film is exposed.

2. The manufacturing method of a semiconductor device as claimed in claim 1, further comprising steps of:
forming a blanket insulating film that covers at least the protective insulating films, before forming the first interlayer insulating film; and
removing the blanket insulating film formed on bottoms of the contact holes, by using the second interlayer insulating film as a mask.

3. The manufacturing method of a semiconductor device as claimed in claim 1, wherein the first interlayer insulating film is a BPSG (Boro-Phospho Silicate Glass) film, and the second interlayer insulating film is an NSG (Non Silicate Glass) film.

4. The manufacturing method of a semiconductor device as claimed in claim 1, wherein the protective insulating films are silicon nitride films.

5. The manufacturing method of a semiconductor device as claimed in claim 1, wherein the protective insulating films have cap insulating films formed on the gate electrodes and sidewall insulating films that cover side surfaces of the gate electrodes and the cap insulating films.

6. The manufacturing method of a semiconductor device as claimed in claim 1, wherein the conductive film is a DOPOS (doped polysilicon) film.

7. The manufacturing method of a semiconductor device as claimed in claim 2, wherein the blanket insulating film is a silicon nitride film.

8. The manufacturing method of a semiconductor device as claimed in claim 1, further comprising a step of forming second contact plugs on the first contact plugs, wherein the second contact plugs are offset to the first contact plugs, respectively.

9. The manufacturing method of a semiconductor device as claimed in claim 1, further comprising a step of selectively forming epitaxial layers on the source/drain diffusion layers, respectively, before forming the first interlayer insulating film, wherein
at the step of forming the plurality of contact holes, the first and second interlayer insulating films are etched until top surfaces of the epitaxial layers are exposed.

10. The manufacturing method of a semiconductor device as claimed in claim 2, further comprising a step of selectively forming epitaxial layers on the source/drain diffusion layers, respectively, before forming the first interlayer insulating film, wherein
at the step of forming the plurality of contact holes, the first and second interlayer insulating films are etched until top surfaces of the epitaxial layers are exposed.

11. The manufacturing method of a semiconductor device as claimed in claim 3, further comprising a step of selectively forming epitaxial layers on the source/drain diffusion layers, respectively, before forming the first interlayer insulating film, wherein
at the step of forming the plurality of contact holes, the first and second interlayer insulating films are etched until top surfaces of the epitaxial layers are exposed.

12. The manufacturing method of a semiconductor device as claimed in claim 4, further comprising a step of selectively forming epitaxial layers on the source/drain diffusion layers, respectively, before forming the first interlayer insulating film, wherein
at the step of forming the plurality of contact holes, the first and second interlayer insulating films are etched until top surfaces of the epitaxial layers are exposed.

13. The manufacturing method of a semiconductor device as claimed in claim 5, further comprising a step of selectively forming epitaxial layers on the source/drain diffusion layers, respectively, before forming the first interlayer insulating film, wherein
at the step of forming the plurality of contact holes, the first and second interlayer insulating films are etched until top surfaces of the epitaxial layers are exposed.

14. The manufacturing method of a semiconductor device as claimed in claim 6, further comprising a step of selectively forming epitaxial layers on the source/drain diffusion layers, respectively, before forming the first interlayer insulating film, wherein
at the step of forming the plurality of contact holes, the first and second interlayer insulating films are etched until top surfaces of the epitaxial layers are exposed.

15. The manufacturing method of a semiconductor device as claimed in claim 7, further comprising a step of selectively forming epitaxial layers on the source/drain diffusion layers, respectively, before forming the first interlayer insulating film, wherein
at the step of forming the plurality of contact holes, the first and second interlayer insulating films are etched until top surfaces of the epitaxial layers are exposed.

16. The manufacturing method of a semiconductor device as claimed in claim 8, further comprising a step of selectively forming epitaxial layers on the source/drain diffusion layers, respectively, before forming the first interlayer insulating film, wherein
at the step of forming the plurality of contact holes, the first and second interlayer insulating films are etched until top surfaces of the epitaxial layers are exposed.

17. A semiconductor device, comprising:
a plurality of gate electrodes formed on a semiconductor substrate;
a plurality of protective insulating films that cover a top surface and side surfaces of each of the plurality of gate electrodes;
a plurality of source/drain diffusion layers formed in the semiconductor substrate;
a first interlayer insulating film arranged between the plurality of protective insulating films;
a second interlayer insulating film formed on an upper layer of the first interlayer insulating film; and
a plurality of first contact plugs arranged in a manner of penetrating the first and second interlayer insulating films, having bottom surfaces each being electrically connected to the source/drain diffusion layers, and configured such that top surfaces are approximately flush with a top surface of the second interlayer insulating film.

18. The semiconductor device as claimed in claim 17, further comprising:
a third interlayer insulating film formed on an upper layer of the second interlayer insulating film; and
second contact plugs arranged in a manner of penetrating the third interlayer insulating film and electrically connected to the first contact plugs, wherein
the second contact plugs are offset to the first contact plugs, respectively.

19. The semiconductor device as claimed in claim 17, wherein the first contact plugs are electrically connected via epitaxial layers to the source/drain diffusion layers, respectively.

20. The semiconductor device as claimed in claim 18, wherein the first contact plugs are electrically connected via epitaxial layers to the source/drain diffusion layers, respectively.
